(19) United States
(12) Patent Application Publication
(10) Pub. No.: US 2026/0032937 A1
(43) Pub. Date: Jan. 29, 2026

(54) SEMICONDUCTOR DEVICE

(71) Applicant: Mitsubishi Electric Corporation, Tokyo (JP)

(72) Inventors: Masaki SUDO, Tokyo (JP); Masanori TSUKUDA, Tokyo (JP)

(73) Assignee: Mitsubishi Electric Corporation, Tokyo (JP)

(21) Appl. No.: 19/200,374

(22) Filed: May 6, 2025

(30) Foreign Application Priority Data
Jul. 24, 2024 (JP) 2024-118350

(51) Int. Cl. H10D 12/00

(52) U.S. Cl. CPC H10D 12/415; H10D 12/416; H10D 12/481

(57) ABSTRACT

An object of the present disclosure is to suppress carrier injection in a termination region even with a malfunction in a back gate operation, in a semiconductor device with a double-sided gate structure. A semiconductor device with the double-sided gate structure includes: a buffer layer of a first conductivity type on a back surface of a drift layer; and a collector layer of a second conductivity type between the buffer layer and a collector electrode in an element region. A termination region does not include the collector layer between the collector electrode and the buffer layer, or the termination region includes the collector layer between the collector electrode and the buffer layer such that the collector layer in the termination region is less in total impurity quantity of the second conductivity type per unit area than the collector layer in the element region.

### BACKGROUND

### Technical Field

The present disclosure relates to a semiconductor device that has a double-sided gate structure and can bidirectionally conduct a current.

### Description of the Background Art

Japanese Patent No. 7407757 discloses a semiconductor device that has a double-sided gate structure including gate electrodes on a front side and a back side of a semiconductor layer. The semiconductor device described in Japanese Patent No. 7407757 performs a back gate operation for turning ON transistors on the back side during a turn-off operation. This suppresses injection of holes into a drift region in an element region to reduce the turn-off loss.

The semiconductor device described in Japanese Patent No. 7407757, however, has a problem of a decrease in the ruggedness due to a failure in suppressing carrier injection from a termination region to the element region when a malfunction in the back gate operation occurs.

### SUMMARY

An object of the present disclosure is to suppress carrier injection in a termination region even with a malfunction in a back gate operation, in a semiconductor device with a double-sided gate structure.

One semiconductor device according to the present disclosure is divided, in a plan view, into an element region in which a main current flows, and a termination region surrounding the element region. The semiconductor device includes a semiconductor substrate, an emitter electrode, a collector electrode, a front gate electrode, a back gate electrode, a buffer layer of a first conductivity type, and a collector layer of a second conductivity type. The semiconductor substrate includes a drift layer of the first conductivity type. The emitter electrode is disposed on a front surface of the semiconductor substrate. The collector electrode is disposed on a back surface of the semiconductor substrate. The front gate electrode is disposed in the front surface of the semiconductor substrate in the element region. The back gate electrode is disposed in the back surface of the semiconductor substrate in the element region. The buffer layer is disposed on a back surface of the drift layer. The collector layer is disposed between the buffer layer and the collector electrode in the element region. The termination region does not include the collector layer of the second conductivity type between the collector electrode and the buffer layer, or the termination region includes the collector layer of the second conductivity type between the collector electrode and the buffer layer such that the collector layer of the second conductivity type in the termination region is less in total impurity quantity of the second conductivity type per unit area than the collector layer of the second conductivity type in the element region.

The one semiconductor device according to the present disclosure can suppress hole injection from the back surface of the termination region without any back gate structure in the termination region. Thus, the semiconductor device can suppress the carrier injection in the termination region even with a malfunction in a back gate operation.

These and other objects, features, aspects, and advantages of the present disclosure will become more apparent from the following detailed description of the present disclosure when taken in conjunction with the accompanying drawings.

### BRIEF DESCRIPTION OF THE DRAWINGS

FIG. 1 is a top view of a semiconductor device;

FIG. 2 is a cross-sectional view of a semiconductor device according to Embodiment 1;

FIG. 3 is a cross-sectional view of a semiconductor device according to Embodiment 2;

FIG. 4 is a cross-sectional view of a semiconductor device according to Embodiment 3;

FIG. 5 is a cross-sectional view of a semiconductor device according to Embodiment 4;

FIG. 6 is a cross-sectional view of a semiconductor device according to Embodiment 5;

FIG. 7 is a cross-sectional view of a semiconductor device according to Embodiment 6; and

FIG. 8 is a cross-sectional view of a semiconductor device according to Embodiment 7.

### DESCRIPTION OF THE PREFERRED EMBODIMENTS

### A. Embodiment 1

### [A-1. Structure]

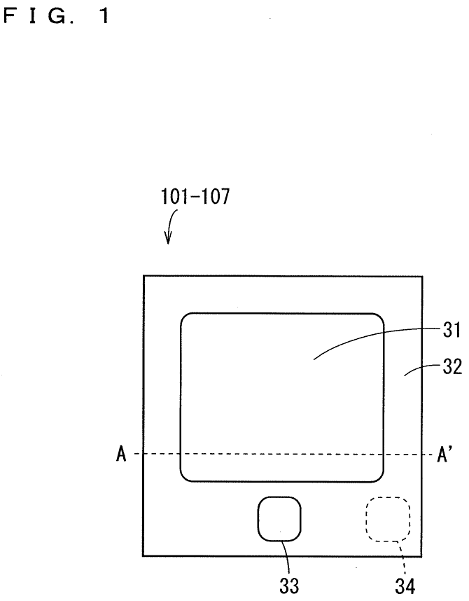

FIG. 1 is a top view of a semiconductor device 101 according to Embodiment 1. The semiconductor device 101 is an insulated-gate bipolar transistor (IGBT). As illustrated in FIG. 1, the semiconductor device 101 is divided into an element region 31 and a termination region 32 in a plan view. The element region 31 is a region in which semiconductor elements are formed and a main current flows. The termination region 32 surrounds the element region 31, and includes an emitter-side gate pad region 33 and a collector-side gate pad region 34. FIG. 1 also illustrates top views of semiconductor devices according to other Embodiments in this Specification.

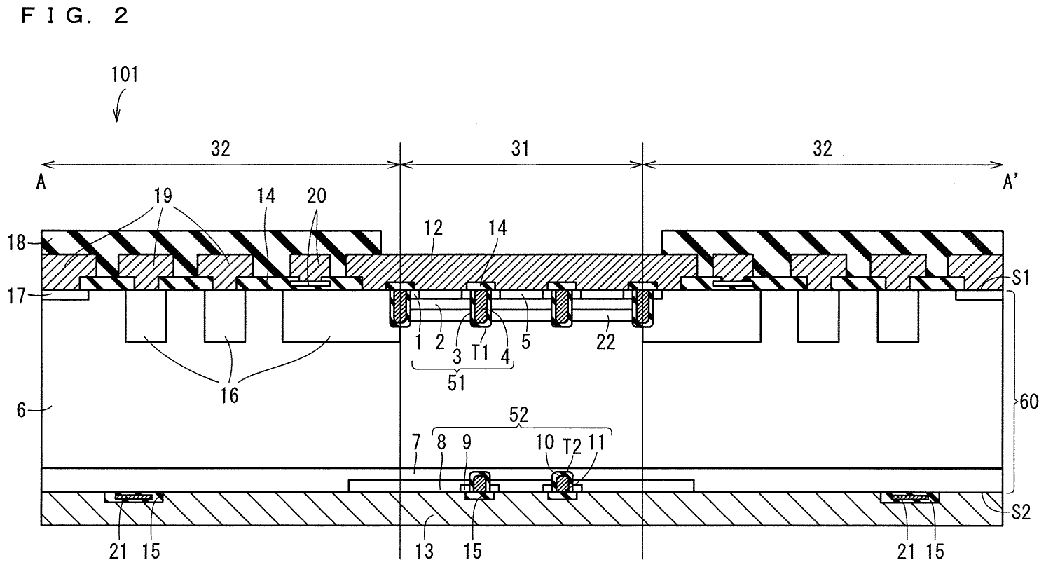

FIG. 2 is a cross-sectional view of the semiconductor device 101 which is taken along a line A-A′ in FIG. 1. As illustrated in FIG. 2, the semiconductor device 101 includes a semiconductor substrate 60. The semiconductor substrate 60 includes a first main surface S1 that is a front main surface, and a second main surface S2 that is a back main surface. The second main surface S2 is a main surface opposite to the first main surface S1. The first main surface S1 will also be referred to as a front surface of the semiconductor substrate 60, and the second main surface S2 will also be referred to as a back surface of the semiconductor substrate 60.

First, a structure of the element region 31 will be described. The semiconductor device 101 includes, in the element region 31, the semiconductor substrate 60, an emitter electrode 12, an emitter-side interlayer film 14, a collector-side interlayer film 15, and a collector electrode 13. The semiconductor substrate 60 includes, in the element region 31, an n-type drift layer 6, an n-type buffer layer 7, an emitter-side MOS channel portion 51, and a collector-side MOS channel portion 52. The n-type drift layer 6 functions as a breakdown voltage retaining portion. The emitter-side MOS channel portion 51 is disposed closer to the first main surface S1 in the n-type drift layer 6. The emitter electrode 12 that is a main electrode portion is disposed on the first main surface S1.

The emitter-side MOS channel portion 51 includes an n-type source layer 1, a p-type base layer 2, emitter-side oxide films 3, and emitter-side gate electrodes 4. The p-type base layer 2 is formed closer to the first main surface S1 in the n-type drift layer 6. The n-type source layer 1 and a p-type contact layer 5 are formed closer to the first main surface S1 with respect to the p-type base layer 2. The upper surface of the n-type source layer 1 and the p-type contact layer 5 is the first main surface S1.

Trenches T1 that penetrate the n-type source layer 1 and the p-type base layer 2 from the first main surface S1 and reach the n-type drift layer 6 are formed. In each of the trenches T1, the emitter-side gate electrode 4 is embedded through the emitter-side oxide film 3. The emitter-side interlayer film 14 is disposed between the emitter-side gate electrodes 4 and the emitter electrode 12 to insulate the emitter-side gate electrodes 4 from the emitter electrode 12.

The n-type buffer layer 7 is disposed closer to the second main surface S2 with respect to the n-type drift layer 6. The collector-side MOS channel portion 52 is disposed closer to the second main surface S2 with respect to the n-type buffer layer 7. The collector electrode 13 that is a main electrode portion is disposed on the second main surface S2.

The collector-side MOS channel portion 52 includes a p-type collector layer 8, an n-type collector layer 9, collector-side oxide films 10, and collector-side gate electrodes 11. The p-type collector layer 8 is formed closer to the second main surface S2 with respect to the n-type buffer layer 7. The lower surface of the p-type collector layer 8 is the second main surface S2. The n-type collector layer 9 is disposed in a part of a surface layer of the p-type collector layer 8 closer to the second main surface S2.

Trenches T2 that penetrate the n-type collector layer 9 and the p-type collector layer 8 from the second main surface S2 and reach the n-type buffer layer 7 are formed. In each of the trenches T2, the collector-side gate electrode 11 is embedded through the collector-side oxide film 10. The collector-side interlayer film 15 is disposed between the collector-side gate electrodes 11 and the collector electrode 13 to insulate the collector-side gate electrodes 11 from the collector electrode 13.

An emitter-side n-type layer 22 is formed shallower than bottoms of the emitter-side gate electrodes 4, between the p-type base layer 2 and the n-type drift layer 6 that is the breakdown voltage retaining portion. Intervals of repeatedly arranging the emitter-side gate electrode 4 (an emitter-side gate pitch) need not be identical to intervals of repeatedly arranging the collector-side gate electrode 11 (a collector-side gate pitch).

Next, a structure of the termination region 32 will be described. The semiconductor device 101 includes, in the termination region 32, the n-type drift layer 6 that is the breakdown voltage retaining portion. A plurality of p-type well layers 16 and an n-type channel stopper layer 17 are disposed in a part of a surface layer of the n-type drift layer 6 closer to the first main surface S1. The n-type channel stopper layer 17 is disposed at a peripheral end of the semiconductor device 101.

The emitter-side interlayer film 14, a field plate 19, and an emitter-side gate liner 20 are disposed on the first main surface S1. Openings of the emitter-side interlayer film 14 are formed on the n-type channel stopper layer 17 and the p-type well layers 16 except the one that is the closest to the element region 31. The field plate 19 is in contact with the p-type well layers 16 or the n-type channel stopper layer 17 through the openings of the emitter-side interlayer film 14. The opening of the emitter-side interlayer film 14 may be formed on the p-type well layer 16 that is the closest to the element region 31 in the p-type well layers 16, and the field plate 19 may be in contact with the p-type well layer 16 through this opening. The emitter-side interlayer film 14 insulates the emitter-side gate liner 20 from the p-type well layers 16. A passivation film 18 is disposed on the emitter-side interlayer film 14, the field plate 19, and the emitter-side gate liner 20.

The collector electrode 13 and a collector-side gate liner 21 are disposed on the second main surface S2. The collector-side interlayer film 15 insulates the collector-side gate liner 21 from the collector electrode 13. Although the termination region 32 with a field limiting ring (FLR) structure is described above, the termination region 32 may have a reduced surface electric field (RESURF) structure or a variation of lateral doping (VLD) structure.

The element region 31 includes the p-type collector layer 8 between the collector electrode 13 and the n-type buffer layer 7. However, the termination region 32 does not include the p-type collector layer 8 between the collector electrode 13 and the n-type buffer layer 7. Alternatively, although the termination region 32 includes the p-type collector layer 8 between the collector electrode 13 and the n-type buffer layer 7, the p-type collector layer 8 in the termination region 32 is less in acceptor quantity per unit area in a plan view than the p-type collector layer 8 in the element region 31. The less acceptor quantity per unit area means that the p-type collector layer 8 is thin or the acceptor concentration of the p-type collector layer 8 is low. Such a structure suppresses carrier injection in the termination region. In other words, the structure on the back surface of the termination region 32 functions as a carrier injection suppressor that suppresses carrier injection in the termination region.

The peak concentration of the n-type source layer 1 approximately ranges from 10¹⁸ cm⁻³ to 10²¹ cm³. The peak concentration of the p-type base layer 2 is approximately 10¹⁷ cm⁻³ or lower. The peak concentration of the emitter-side n-type layer 22 approximately ranges from 10¹⁵ cm⁻³ to 10¹⁷ cm³. The peak concentration of the n-type buffer layer 7 approximately ranges from 10¹⁵ cm⁻³ to 10¹⁸ cm³. The peak concentration of the p-type collector layer 8 approximately ranges from 10¹⁷ cm⁻³ to 10¹⁹ cm³. The peak concentration of a collector-side n-type layer approximately ranges from 10¹⁸ cm⁻³ to 10²¹ cm³.

The concentration of the n-type drift layer 6 approximately ranges from 10¹² cm⁻³ to 10¹⁴ cm³. The peak concentration of the p-type well layers 16 approximately ranges from 10¹⁶ cm⁻³ to 10¹⁸ cm³. The peak concentration of the n-type channel stopper layer 17 approximately ranges from 10¹⁸ cm⁻³ to 10²¹ cm³.

### [A-2. Operations]

With application of a positive voltage to the emitter-side gate electrodes 4, an emitter-side MOS channel connects the n-type source layer 1 to the breakdown voltage retaining portion to allow the IGBT to enter the ON state. When application of the positive voltage to the emitter-side gate electrodes 4 is stopped, the IGBT enters the OFF state. With application of a positive voltage to the collector-side gate electrodes 11 at turn off, a collector-side MOS channel connects the n-type collector layer 9 to the n-type buffer layer 7. This also refers to a back gate operation. Since this reduces the hole injection efficiency in the p-type collector layer 8, a current can be blocked at high speeds. However, when a malfunction in the back gate operation occurs at turn off, the hole injection efficiency in the p-type collector layer 8 does not decrease. Thus, carriers in the element region 31 and the termination region 32 increase. Accordingly, the increase in the carriers in the termination region 32 reduces the ruggedness.

In the semiconductor device 101 according to Embodiment 1, the termination region 32 does not include the p-type collector layer 8, or the p-type collector layer 8 in the termination region 32 is less in acceptor quantity per unit area than the p-type collector layer 8 in the element region 31. The p-type collector layer 8 is a source of hole injection. Thus, when the IGBT is in ON state, the hole injection efficiency from the back surface of the termination region 32 decreases, so that the carriers in the termination region 32 can be reduced in the semiconductor device 101.

Thus, the semiconductor device 101 according to Embodiment 1 can reduce the carriers in the termination region 32 without any back gate structure in the termination region 32. Consequently, a decrease in the ruggedness can be avoided even with a malfunction in the back gate operation.

Furthermore, the termination region 32 can be used as a diode. Since the impurity concentration of the n-type buffer layer 7 is low and the carrier injection efficiency in a diode operation is low, the ruggedness does not decrease even when the termination region 32 is used as a diode.

### B. Embodiment 2

### [B-1. Structure]

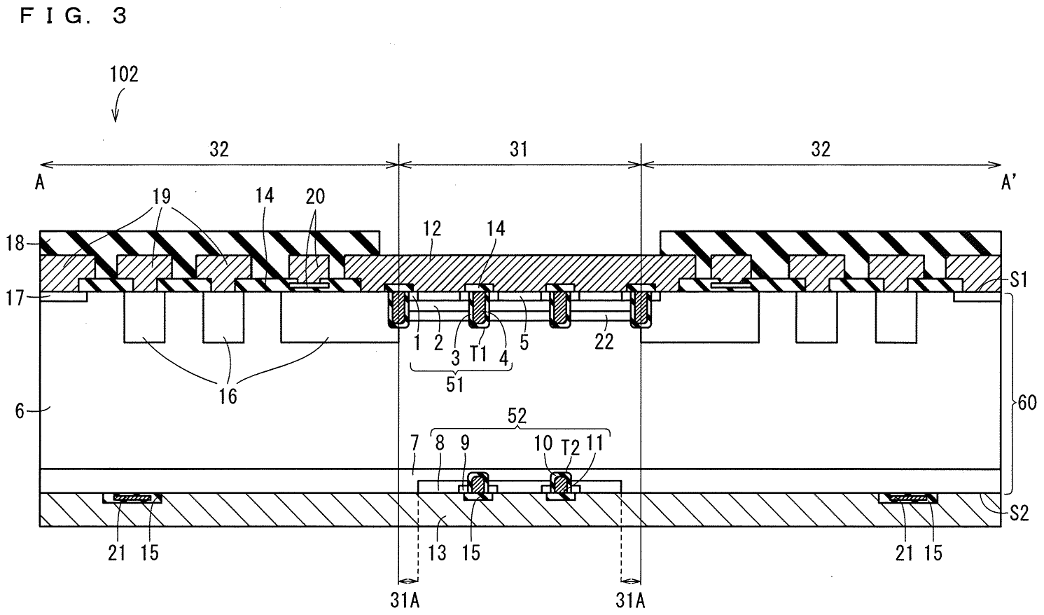

FIG. 3 is a cross-sectional view of a semiconductor device 102 according to Embodiment 2 which is taken along the line A-A′ in FIG. 1. The semiconductor device 102 has a structure different from that of the semiconductor device 101 according to Embodiment 1 in an element-region end portion 31A that is a portion of the element region 31 in the vicinity of the termination region 32. In other words, the element-region end portion 31A of the semiconductor device 102 does not include the p-type collector layer 8 between the collector electrode 13 and the n-type buffer layer 7. Alternatively, although the element-region end portion 31A includes the p-type collector layer 8, the p-type collector layer 8 in the element-region end portion 31A is less in acceptor quantity per unit area in a plan view than the p-type collector layer 8 in a portion of the element region 31 except the element-region end portion 31A. The structure of the semiconductor device 102 except the element-region end portion 31A is identical to that of the semiconductor device 101.

### [B-2. Operations]

The semiconductor device 102 according to Embodiment 2 has the following advantages in addition to the advantages of the semiconductor device 101 according to Embodiment 1.

The termination region 32 and the element-region end portion 31A in the semiconductor device 102 do not include the p-type collector layer 8, or the p-type collector layer 8 in the termination region 32 is less in acceptor quantity per unit area than the p-type collector layer 8 in the element region 31. The p-type collector layer 8 is a source of hole injection. Since holes are not injected when the IGBT is ON or the influence is less in the termination region 32 and the element-region end portion 31A of the semiconductor device 102, the hole injection efficiency in the termination region 32 and the element-region end portion 31A decreases, so that carriers in the termination region 32 can be reduced.

Thus, the semiconductor device 102 according to Embodiment 2 can reduce the carriers in the termination region 32 without any back gate structure in the termination region 32 and the element-region end portion 31A. Consequently, a decrease in the ruggedness can be avoided even with a malfunction in the back gate operation.

### C. Embodiment 3

### [C-1. Structure]

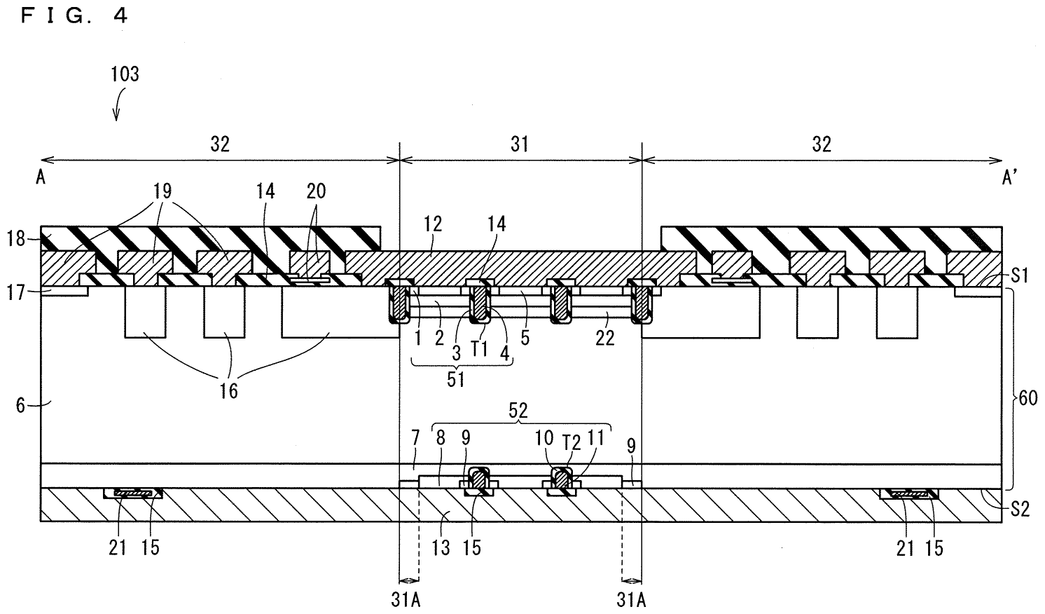

FIG. 4 is a cross-sectional view of a semiconductor device 103 according to Embodiment 3 which is taken along the line A-A′ in FIG. 1. The semiconductor device 103 differs from the semiconductor device 101 according to Embodiment 1 only in including the n-type collector layer 9 between the collector electrode 13 and the n-type buffer layer 7 instead of the p-type collector layer 8 in the element-region end portion 31A that is a portion of the element region 31 in the vicinity of the termination region 32.

### [C-2. Operations]

The semiconductor device 103 according to Embodiment 3 has the following advantages in addition to the advantages of the semiconductor device 101 according to Embodiment 1.

Since electrons easily flow through the n-type collector layer 9 in the element-region end portion 31A so that electrons entering the p-type collector layer 8 are reduced, hole injection from the p-type collector layer 8 in the vicinity of the n-type collector layer 9 can be reduced. Since this reduces the hole injection efficiency in the vicinity of the element-region end portion 31A, the carriers in the termination region 32 can be reduced.

### D. Embodiment 4

### [D-1. Structure]

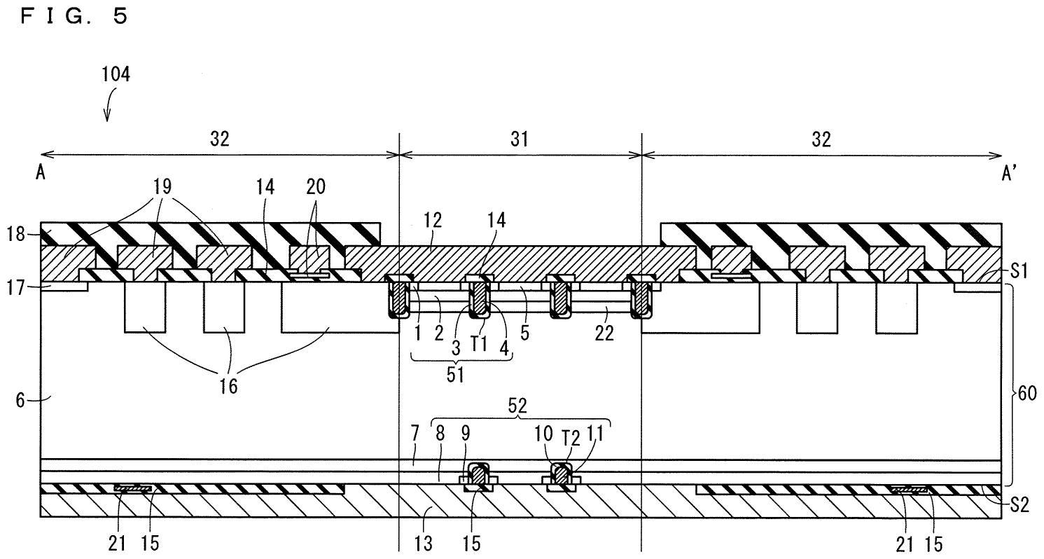

FIG. 5 is a cross-sectional view of a semiconductor device 104 according to Embodiment 4 which is taken along the line A-A′ in FIG. 1. The semiconductor device 104 differs in the termination region 32 from the semiconductor device 101 according to Embodiment 1 only in including the p-type collector layer 8 closer to the second main surface S2 with respect to the n-type buffer layer 7, and the collector-side interlayer film 15 between the p-type collector layer 8 and the collector electrode 13.

### [D-2. Operations]

The collector-side interlayer film 15 insulates the collector electrode 13 from the p-type collector layer 8 in the termination region 32. Thus, when the IGBT is ON, hole injection from the p-type collector layer 8 in the termination region 32 is suppressed. Since this reduces the hole injection efficiency in the termination region 32, the carriers in the termination region 32 can be reduced.

Consequently, the semiconductor device 104 according to Embodiment 4 can reduce the carriers in the termination region 32 without any back gate structure in the termination region 32. Thus, a decrease in the ruggedness can be avoided even with a malfunction in the back gate operation.

### E. Embodiment 5

### [E-1. Structure]

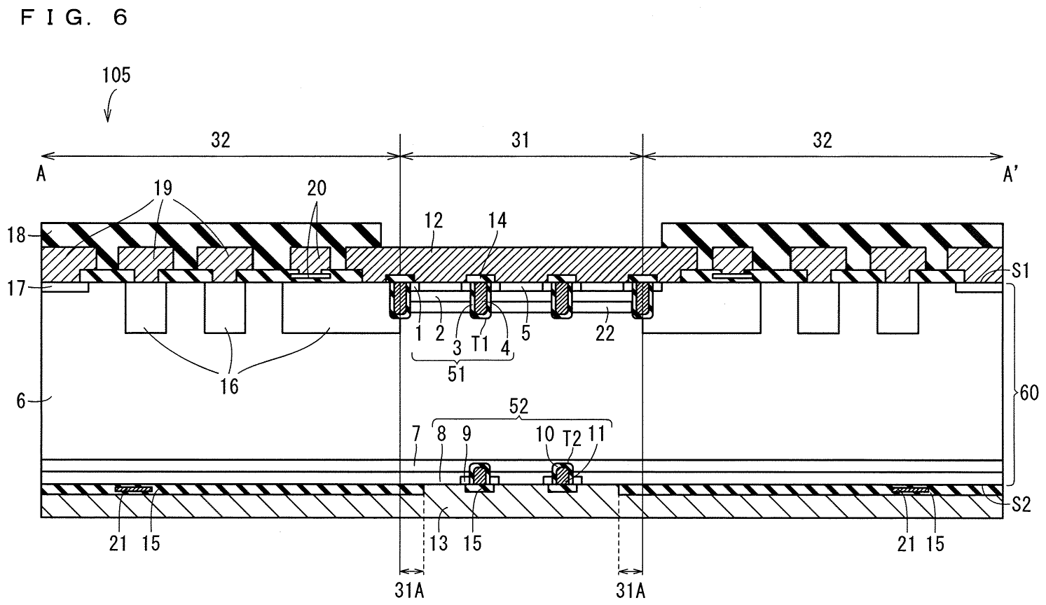

FIG. 6 is a cross-sectional view of a semiconductor device 105 according to Embodiment 5 which is taken along the line A-A′ in FIG. 1. The semiconductor device 105 differs from the semiconductor device 104 according to Embodiment 4 only in including the collector-side interlayer film 15 between the p-type collector layer 8 and the collector electrode 13 in the termination region 32 and the element-region end portion 31A.

### [E-2. Operations]

The collector-side interlayer film 15 insulates the collector electrode 13 from the p-type collector layer 8 in the termination region 32 and the element-region end portion 31A. Thus, when the IGBT is ON, the hole injection from the p-type collector layer 8 in the termination region 32 and the element-region end portion 31A is suppressed. Since this reduces the hole injection efficiency in the termination region 32, the carriers in the termination region 32 can be reduced.

Consequently, the semiconductor device 105 according to Embodiment 5 can reduce the carriers in the termination region 32 without any back gate structure in the termination region 32 and the element-region end portion 31A. Thus, a decrease in the ruggedness can be avoided even with a malfunction in the back gate operation.

### F. Embodiment 6

### [F-1. Structure]

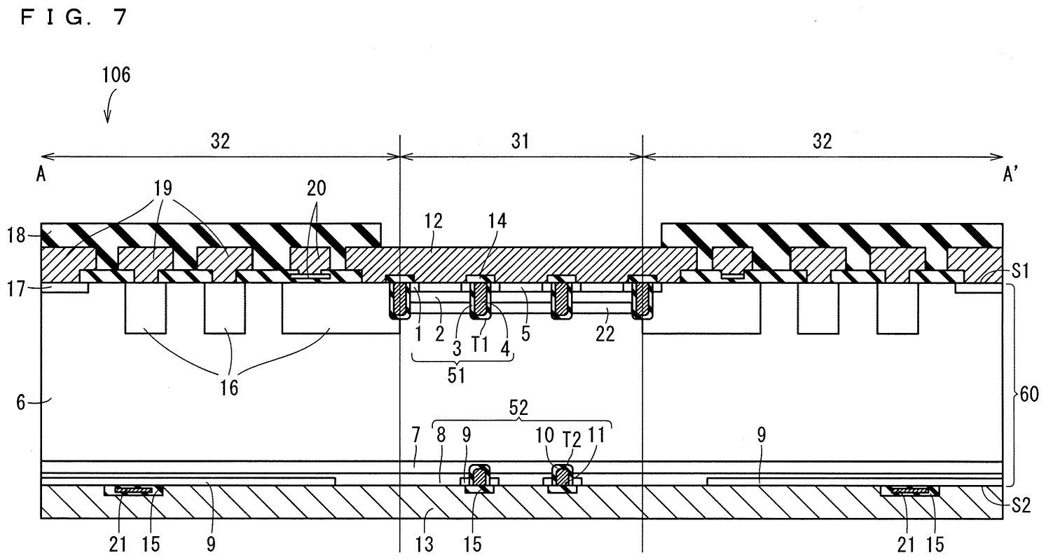

FIG. 7 is a cross-sectional view of a semiconductor device 106 according to Embodiment 6 which is taken along the line A-A′ in FIG. 1. The semiconductor device 106 differs in the termination region 32 from the semiconductor device 104 according to Embodiment 4 only in including the n-type collector layer 9 between the p-type collector layer 8 and the collector electrode 13.

### [F-2. Operations]

Since the n-type collector layer 9 is disposed between the p-type collector layer 8 and the collector electrode 13, the p-type collector layer 8 is not in contact with the collector electrode 13 in the termination region 32. Thus, when the IGBT is ON, the hole injection from the p-type collector layer 8 in the termination region 32 is suppressed. Since this reduces the hole injection efficiency in the termination region 32, the carriers in the termination region 32 can be reduced.

Consequently, the semiconductor device 106 according to Embodiment 6 can reduce the carriers in the termination region 32 without any back surface gate. Thus, a decrease in the ruggedness can be avoided even with a malfunction in the back gate operation.

### G. Embodiment 7

### [G-1. Structure]

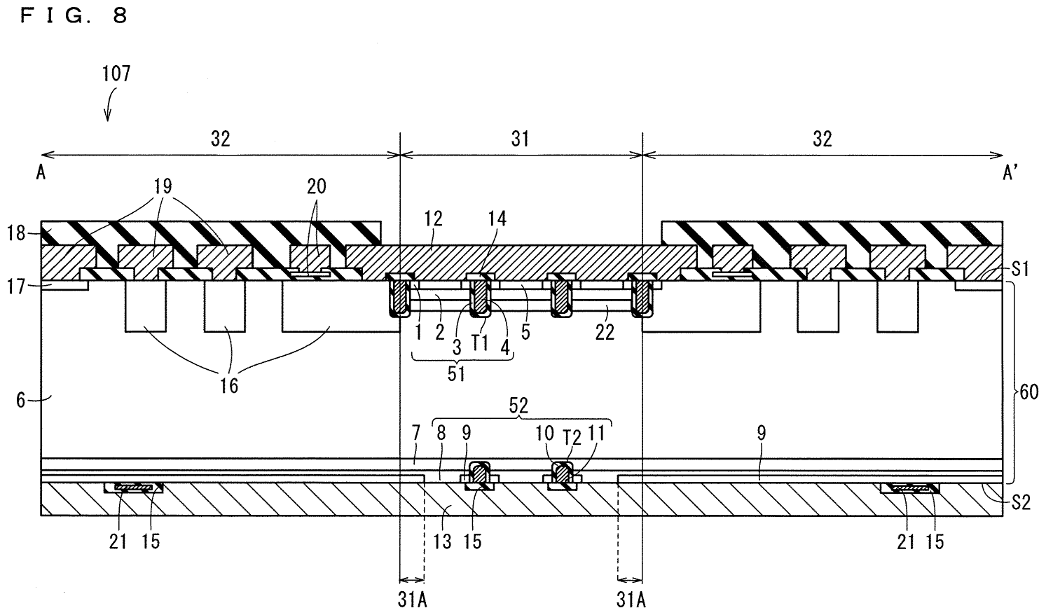

FIG. 8 is a cross-sectional view of a semiconductor device 107 according to Embodiment 7 which is taken along the line A-A′ in FIG. 1. The semiconductor device 107 differs from the semiconductor device 106 according to Embodiment 6 only in including the n-type collector layer 9 between the p-type collector layer 8 and the collector electrode 13 in the termination region 32 and the element-region end portion 31A.

### [G-2. Operations]

Since the n-type collector layer 9 is disposed between the p-type collector layer 8 and the collector electrode 13 in the termination region 32 and the element-region end portion 31A, the p-type collector layer 8 is not in contact with the collector electrode 13. Thus, when the IGBT is ON, the hole injection from the p-type collector layer 8 in the termination region 32 and the element-region end portion 31A is suppressed. Since this reduces the hole injection efficiency in the termination region 32, the carriers in the termination region 32 can be reduced.

Consequently, the semiconductor device 107 according to Embodiment 7 can reduce the carriers in the termination region 32 without any back surface gate. Thus, a decrease in the ruggedness can be avoided even with a malfunction in the back gate operation.

Although preferred embodiments are described above in detail, various modifications and replacements can be added to Embodiments, etc. without being limited to Embodiments, etc. and without departing from claims.

While the disclosure has been shown and described in detail, the foregoing description is in all aspects illustrative and not restrictive. It is therefore understood that numerous modifications and variations can be devised.

What is claimed is:

1. A semiconductor device divided, in a plan view, into an element region in which a main current flows, and a termination region surrounding the element region, the semiconductor device comprising:
a semiconductor substrate including a drift layer of a first conductivity type;
an emitter electrode disposed on a front surface of the semiconductor substrate;
a collector electrode disposed on a back surface of the semiconductor substrate;
a front gate electrode disposed in the front surface of the semiconductor substrate in the element region;
a back gate electrode disposed in the back surface of the semiconductor substrate in the element region;
a buffer layer of the first conductivity type, the buffer layer being disposed on a back surface of the drift layer; and
a collector layer of a second conductivity type, the collector layer being disposed between the buffer layer and the collector electrode in the element region,
wherein the termination region does not include the collector layer of the second conductivity type between the collector electrode and the buffer layer, or the termination region includes the collector layer of the second conductivity type between the collector electrode and the buffer layer such that the collector layer of the second conductivity type in the termination region is less in total impurity quantity of the second conductivity type per unit area than the collector layer of the second conductivity type in the element region.

2. The semiconductor device according to claim 1,
wherein an element-region end portion does not include the collector layer of the second conductivity type between the collector electrode and the buffer layer, or the element-region end portion includes the collector layer of the second conductivity type between the collector electrode and the buffer layer such that the collector layer of the second conductivity type in the element-region end portion is less in total impurity quantity of the second conductivity type per unit area than the collector layer of the second conductivity type in a portion of the element region except the element-region end portion, the element-region end portion being located in a vicinity of the termination region in the element region.

3. The semiconductor device according to claim 2,
wherein the element-region end portion does not include the collector layer of the second conductivity type,
the semiconductor device comprising a collector layer of the first conductivity type between the collector electrode and the buffer layer in the element-region end portion.

4. A semiconductor device divided, in a plan view, into an element region in which a main current flows, and a termination region surrounding the element region, the semiconductor device comprising:
a semiconductor substrate including a drift layer of a first conductivity type;
an emitter electrode disposed on a front surface of the semiconductor substrate;
a collector electrode disposed on a back surface of the semiconductor substrate;
a front gate electrode disposed in the front surface of the semiconductor substrate in the element region;
a back gate electrode disposed in the back surface of the semiconductor substrate in the element region;
a buffer layer of the first conductivity type, the buffer layer being disposed on the back surface of the semiconductor substrate;
a collector layer of a second conductivity type, the collector layer being disposed between the buffer layer and the collector electrode in the element region and the termination region; and
a collector-side interlayer film disposed between the collector layer of the second conductivity type and the collector electrode in the termination region.

5. The semiconductor device according to claim 4,
wherein the collector-side interlayer film is disposed between the collector layer of the second conductivity type and the collector electrode in the termination region and an element-region end portion located in a vicinity of the termination region in the element region.

6. A semiconductor device divided, in a plan view, into an element region in which a main current flows, and a termination region surrounding the element region, the semiconductor device comprising:
a semiconductor substrate including a drift layer of a first conductivity type;
an emitter electrode disposed on a front surface of the semiconductor substrate;
a collector electrode disposed on a back surface of the semiconductor substrate;
a front gate electrode disposed in the front surface of the semiconductor substrate in the element region;
a back gate electrode disposed in the back surface of the semiconductor substrate in the element region;
a buffer layer of the first conductivity type, the buffer layer being disposed on the back surface of the semiconductor substrate;
a collector layer of a second conductivity type, the collector layer being disposed between the buffer layer and the collector electrode in the element region and the termination region; and
a collector layer of the first conductivity type, the collector layer being disposed between the collector layer of the second conductivity type and the collector electrode in the termination region.

7. The semiconductor device according to claim 6,
wherein the collector layer of the first conductivity type is disposed between the collector layer of the second conductivity type and the collector electrode in the termination region and an element-region end portion located in a vicinity of the termination region in the element region.
